(19) United States
(12) Patent Application Publication
(10) Pub. No.: US 2007/0166969 A1
(43) Pub. Date: Jul. 19, 2007

(54) SEMICONDUCTOR DEVICE AND METHOD FOR MANUFACTURING THE SAME

(75) Inventors: Shinichiro YANAGI, Tokyo (JP); Yoshitaka Otsu, Hyogo (JP); Takayuki Igarashi, Tokyo (JP); Yasuki Yoshihisa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/623,473

(22) Filed: Jan. 16, 2007

(30) Foreign Application Priority Data
Jan. 18, 2006 (JP) 2006-009471

(51) Int. Cl. H01L 21/425

(52) U.S. Cl. 438/514; 257/E21.12

(57) ABSTRACT

The invention provides a semiconductor device capable of protecting a low-concentration implantation region from contamination, and a method for manufacturing the same. A photoresist is formed on a TEOS film which is formed all over a substrate, and removed by photo engraving so as to be partially left. This photo resist is of a positive or negative type opposite to a type of a photoresist used for formation of a p-offset region and a diffusion region. Then, the TEOS film is etched back except for a portion just under the photoresist. Thereby, a contamination protective film is formed just under the photoresist, and a side wall is formed on a side face of a gate electrode.

### BACKGROUND OF THE INVENTION

1. Field of the Invention

The present invention relates to a semiconductor device and a method for manufacturing the same. In particular, the present invention relates to a semiconductor device having at least a CMOSFET (complementary metal oxide semiconductor field effect transistor) and a method for manufacturing the same.

2. Description of the Background Art

As for conventional semiconductor devices, there has been generally known a technique of using a CMOS (complementary metal oxide semiconductor) process to mix a CMOSFET, a bipolar transistor, an HV (high-voltage) MOSFET (metal oxide semiconductor field effect transistor), a resistor element, and the like, on one silicon substrate.

In such a semiconductor device, since a variety of semiconductor elements are formed simultaneously on the one silicon substrate, a variety of implantation regions are mixed on the one silicon substrate, such as a high-concentration implantation region (not less than 1×10¹⁸ cm⁻³) to form a source-drain and the like, and a low-concentration implantation region (not more than 1×10¹⁷ cm⁻³) to form a drift region of a high-voltage MOSFET and a diffusion region of a diffusion resistor element.

A structure of such a semiconductor device is disclosed in ISPSD2000, pp 331-334, “Multi-voltage device integration technique for 0.5 μm BiCMOS and DMOS process”, T. Terashima et al. and the like. For example, this document discloses, in FIGS. 1 and 6, a CMOS structure of a semiconductor device in which a source-drain region and a drift region (offset region) are mixed on one silicon substrate. Further, Japanese Patent Application Laid-Open No. 7(1995)-78895 discloses a method for manufacturing a Bi-CMOS (bipolar complementary metal oxide semiconductor) integrated circuit in which a CMOSFET and a bipolar transistor are formed on one substrate. Japanese Patent Application Laid-Open No. 10(1998)-125913 discloses a semiconductor device including a high-voltage transistor having an offset region and a method for manufacturing the same.

When the variety of implantation regions exist on the one substrate as described above, the low-concentration implantation region is susceptible to auto-doping and contamination (implantation contamination, various kinds of surface contamination, and the like) occurring in a manufacturing process.

For example, after formation of an LDD (lightly doped drain) structure, the low-concentration implantation region (low-concentration implantation active region) is susceptible to auto-doping. In the LDD structure, after formation of a gate oxide film and a gate electrode on a silicon substrate, an oxide film (about 1000 Å) is deposited by CVD (chemical vapor deposition) or the like, to form a side wall on a side face of the gate electrode by etching. In this formation, without a use of a mask, the oxide film except for the side wall portion is etched, and hence all active regions on the substrate come into a state of exposing silicon. As a result, the low-concentration active region and the high-concentration active region exist on the one substrate, while remaining in the state of exposing silicon, and may thereby be affected by auto-doping in which an impurity component in the high-concentration active region is mixed into the low-concentration active region. It is to be noted that typically the etching for the oxide film is set to over etching. Therefore, a silicon layer of the active region is also slightly etched, forming a structure with a level difference between a silicon interface just under the gate electrode and the silicon interface in the active region.

In a case of a high-voltage pMOSFET (p-channel metal oxide field effect transistor), since the active region has a p-offset region which is the low-concentration implantation region as a drift region, the transistor is susceptible to contamination due to impurities remaining in a resist after implantation of high-concentration impurities (P, B, As, or the like). The high concentration impurities such as implanted into the resist and forming a source-drain region, are said to be not completely removable in resist removal by ashing and thus tend to remain in the resist. In the high-concentration implantation as described above, although the p-offset region formed in the active region is covered with the resist, the region is subject to the contamination due to the remnant impurities in the resist as described above, which may make it impossible to form a desired p-offset region.

Due to the effect of contamination as in the above example, variations are created in concentration and impurity profile of a diffusion layer in the active region, causing troubles such as variations in resistance value of a diffused resistor and defect in withstand voltage.

In particular, a high-voltage pMOSFET in recent years is based on a rule for 0.25 μm CMOS, which requires a use of high-concentration phosphorous not used in the source-drain region in a process in the most previous generation. This causes the problem of contamination affecting the low-concentration implantation region as described above.

### SUMMARY OF THE INVENTION

It is an object of the present invention to provide a semiconductor device capable of protecting a low-concentration implantation region from contamination and a method for manufacturing the same.

A first mode of the present invention is a method for manufacturing a semiconductor device including first region formation step, a contamination protective film formation step, and a second region formation step. The first region formation step is selectively implanting impurities at a low concentration of not more than 1×10¹⁷ cm⁻³ into a semiconductor substrate to form a first region. The contamination protective film formation step is forming a contamination protective film on the first region. The second region formation step is selectively implanting the impurities at a high concentration of not less than 1×10¹⁸ cm⁻³ to form a second region at least either prior to or after the first region formation step and the contamination protective film formation step.

It is possible to protect the first region from contamination of the impurities implanted at the high concentration in formation of the second region.

A second mode of the present invention is a semiconductor device including a first region and a source-drain region. The first region is selectively formed on a semiconductor substrate and contains impurities at a low concentration of not more than 1×10¹⁷ cm⁻³. The source-drain region is selectively formed on the semiconductor substrate, contains impurities at a high concentration of not less than 1×10¹⁸ cm⁻³, and is located with a surface there of below the surface of the first region.

It is possible to protect the first region from contamination of the impurities implanted at the high concentration in formation of the source/drain.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a method for manufacturing a semiconductor device according to Embodiment 1;

FIG. 2 is a sectional view showing the method for manufacturing the semiconductor device according to Embodiment 1;

FIG. 3 is a sectional view showing the method for manufacturing the semiconductor device according to Embodiment 1;

FIG. 4 is a sectional view showing the method for manufacturing the semiconductor device according to Embodiment 1;

FIG. 5 is a sectional view showing the method for manufacturing the semiconductor device according to Embodiment 1;

FIG. 6 is a sectional view showing the method for manufacturing the semiconductor device according to Embodiment 1;

FIG. 7 is a sectional view showing the method for manufacturing the semiconductor device according to Embodiment 1;

FIG. 8 is a sectional view showing the method for manufacturing the semiconductor device according to Embodiment 1;

FIG. 9 is a sectional view showing the method for manufacturing the semiconductor device according to Embodiment 1;

FIG. 10 is a sectional view showing the method for manufacturing the semiconductor device according to Embodiment 1;

FIG. 11 is a sectional view showing the method for manufacturing the semiconductor device according to Embodiment 1;

FIG. 12 is a sectional view showing the method for manufacturing the semiconductor device according to Embodiment 1;

FIG. 13 is a sectional view showing a method for manufacturing a semiconductor device according to Embodiment 2;

FIG. 14 is a sectional view showing the method for manufacturing the semiconductor device according to Embodiment 2;

FIG. 15 is a sectional view showing the method for manufacturing the semiconductor device according to Embodiment 2;

FIG. 16 is a sectional view showing the method for manufacturing the semiconductor device according to Embodiment 2;

FIG. 17 is a sectional view showing the method for manufacturing the semiconductor device according to Embodiment 2;

FIG. 18 is a sectional view showing the method for manufacturing the semiconductor device according to Embodiment 2;

FIG. 19 is a sectional view showing the method for manufacturing the semiconductor device according to Embodiment 2;

FIG. 20 is a sectional view showing the method for manufacturing the semiconductor device according to Embodiment 2;

FIG. 21 is a sectional view showing the method for manufacturing the semiconductor device according to Embodiment 2;

FIG. 22 is a sectional view showing the method for manufacturing the semiconductor device according to Embodiment 2;

FIG. 23 is a sectional view showing the method for manufacturing the semiconductor device according to Embodiment 2;

FIG. 24 is a sectional view showing the method for manufacturing the semiconductor device according to Embodiment 2; and

FIG. 25 is a sectional view showing the method for manufacturing the semiconductor device according to Embodiment 2.

### DESCRIPTION OF THE PREFERRED EMBODIMENTS

A semiconductor device and a method for manufacturing the same according to the present invention are characterized in that a contamination protective film made of a TEOS film or the like is formed in a low-concentration implantation region on a substrate made of a semiconductor. It is thereby possible to protect the low-concentration implantation region from contamination. In the following, each of embodiments of the present invention is specifically described. It is to be noted that in this specification, descriptions are made supposing an impurity concentration of not more than 1×10¹⁷ cm⁻³ as a low concentration and an impurity concentration of not less than 1×10¹⁸ cm⁻³ as a high concentration.

### Embodiment 1

A method for manufacturing a semiconductor device according to Embodiment 1 is characterized as follows. In formation of the above-mentioned contamination protective film, when a prescribed region selectively formed by use of a mask (hereinafter referring to an exposure mask for photo engraving) agrees with a region to be protected from contamination, the mask used for formation of the prescribed region is also used for formation of the contamination protective film. It is thereby possible to reduce the number of steps and kinds of masks, so as to reduce manufacturing cost. Below described are a case where the prescribed region is a p-offset region for a high-voltage pMOSFET (HVpMOS) and a diffusion region of a diffusion resistor element (both being the low-concentration implantation regions) and a case where the prescribed region is not to be silicided.

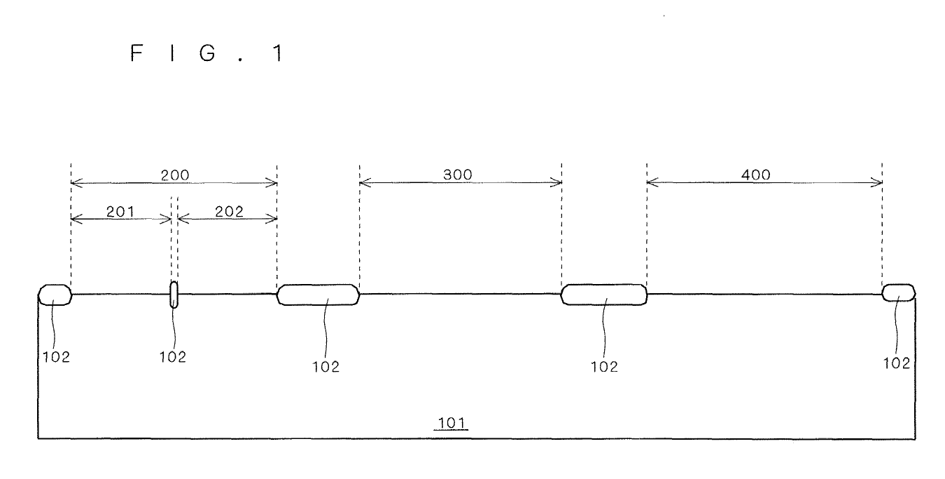

First, as shown in FIG. 1, field oxidation, photo engraving, etching, resist removal, and the like are sequentially performed on a substrate 101 made of a semiconductor to form an element separation film 102. This separates the substrate 101 into a CMOS region 200 where a CMOS element is formed, an HVpMOS region 300 where an HVpMOS element is formed, and a resistor region 400 where a diffusion resistor element is formed. The CMOS region 200 is further separated into a pMOS region 201 and an nMOS region 202.

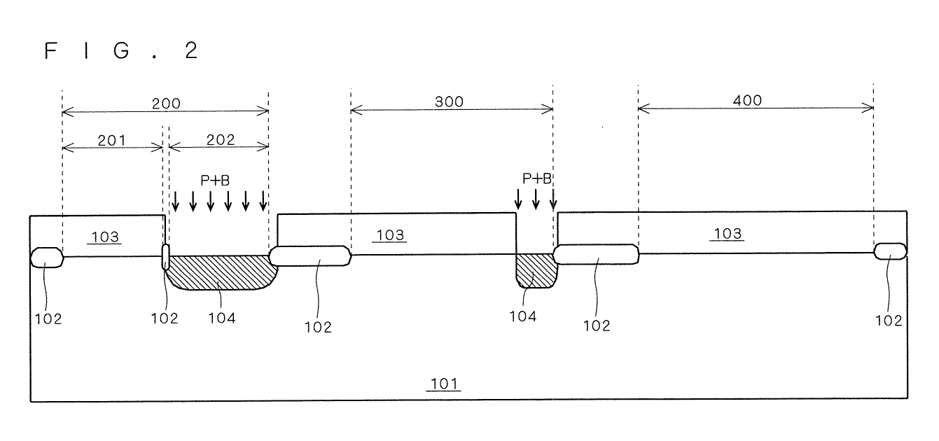

Next, as shown in FIG. 2, a photoresist 103 is formed on the substrate 101, and partially opened by photo engraving. Subsequently, B and high-concentration P are implanted from the above, to form n-wells 104. Thereby, the n-wells 104 (second region) are formed in the regions which are the openings of the photoresist 103 (the entire n-MOS region 202 and part of the right end of the HVpMOS region 300) among the regions on the substrate 101.

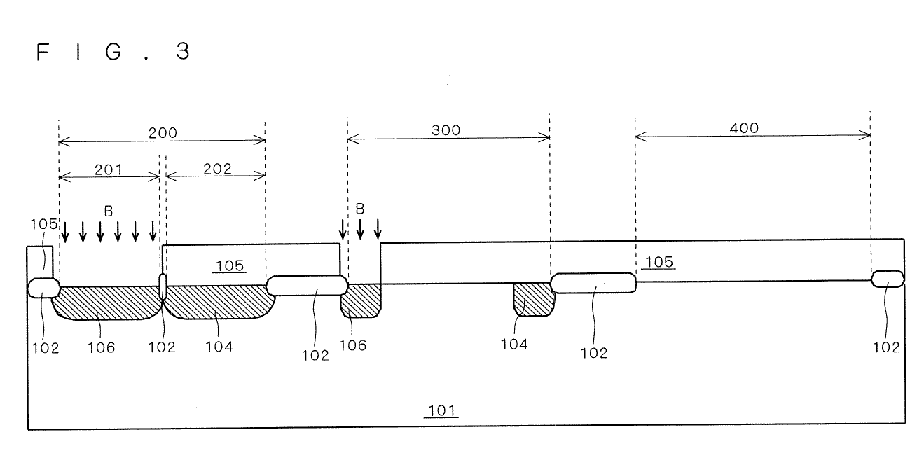

Next, as shown in FIG. 3, the photoresist 103 is removed, and a photoresist 105 is formed on the substrate 101 and partially opened by photo engraving. Subsequently, B is implanted from the above to form p-wells 106. Thereby, the p-wells 106 are formed in regions which are the openings of the photoresist 105 (the entire pMOS region 201 and part of the left end of the HVpMOS region 300) among the regions on the substrate 101.

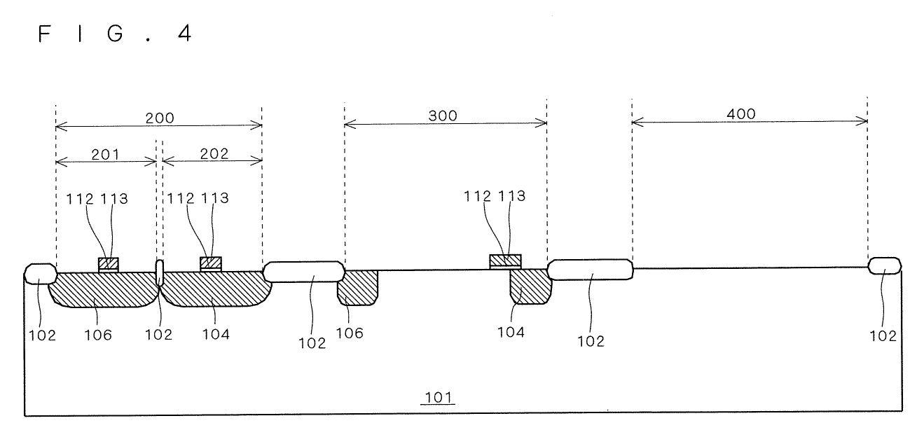

Next, as shown in FIG. 4, gate oxidation, silicon deposition, photo engraving, etching, resist removal, and the like are sequentially performed on the substrate 101, to partially form the gate oxide film 112 and the gate electrode 113 in the pMOS region 201, the nMOS region 202 and the HVpMOS region 300. It is to be noted that the gate oxide film 112 and the gate electrode 113 are disposed in about the center of each of the pMOS region 201 and the nMOS region 202, while being disposed in the right side position of the HVpMOS region 300 so as to be out of contact with the p-well 106 and in contact with the n-well 104.

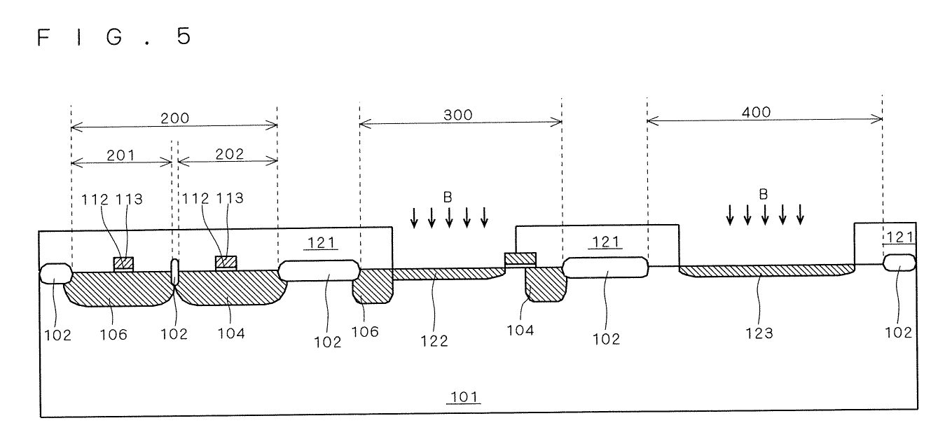

Next, as shown in FIG. 5, photoresist 121 is formed on the substrate 101, and partially opened by photo engraving. Subsequently, low concentration-B is implanted from the above, to form a p-offset region 122 and a diffusion region 123. Thereby, the p-offset region 122 (between the p-well 106 and the gate electrode 113) and the diffusion region 123 (about the center of the resistor region 400) are formed in the regions which are the openings of the photoresist 121 among the regions on the substrate 101. The p-offset region 122 serves to make the impurity concentration low in the active region between the p-well 106 and the gate electrode 113, to enhance a withstand voltage of the HVpMOS. Disposing the p-offset region 122 in the active region enables effective use of the region to make the element small in size. Further, the diffusion region 123 is a diffusion resistor region where the impurity concentration was lowered to increase the resistance value. Namely, the p-offset region 122 and the diffusion region 123 correspond to the first region according to the present invention.

Since being the low-concentration implantation regions, the p-offset region 122 and the diffusion region 123 are required to be protected from contamination, as described above. In the present embodiment, in a later process, a contamination protective film 133 is formed on the p-offset region 122 and the diffusion region 123 by use of a photoresist 132. Namely, the photoresist 132 is of positive or negative type opposite to the type of the photoresist 121, and can be formed by use of the same mask.

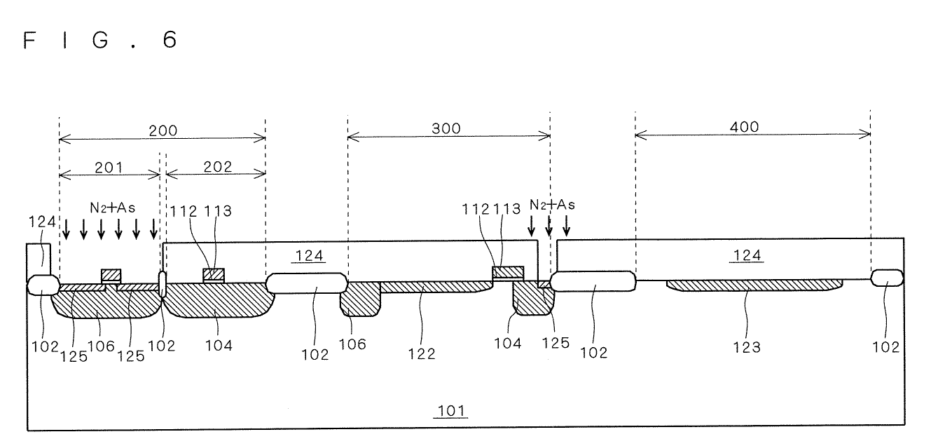

Next, as shown in FIG. 6, the photoresist 121 is removed, and a photoresist 124 is formed on the substrate 101 and partially opened by photo engraving. Subsequently, N₂ and As are implanted from the above to form LDD regions 125. Thereby, the LDD regions 125 are formed in the regions which are the openings of the photoresist 124 and where the gate electrode 113 is not disposed (the outside of the gate electrode 113 of the p-well 106 in the nMOS region 202 and the right end of the n-well 104 at the right end of the HVpMOS region 300) among the regions on the substrate 101.

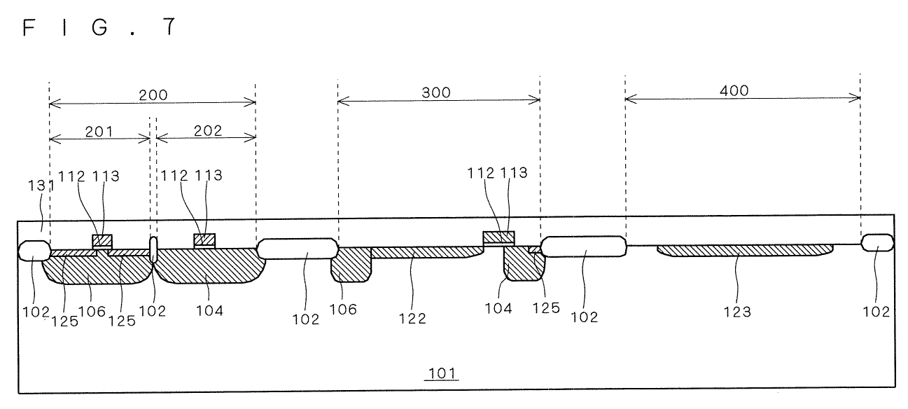

Next, as shown in FIG. 7, the photoresist 124 is removed and a TEOS (tetraethoxysilane) film 131 with a thickness of not less than 1000 Å is formed all over the substrate 101. It is to be noted that the TEOS film 131 serves to form the side wall 114 and the contamination protective film 133 in a later process. Further, the oxide film formed in this step is not limited to TEOS but another oxide film made of NSG (non-doped silicate glass) or the like may also be applied.

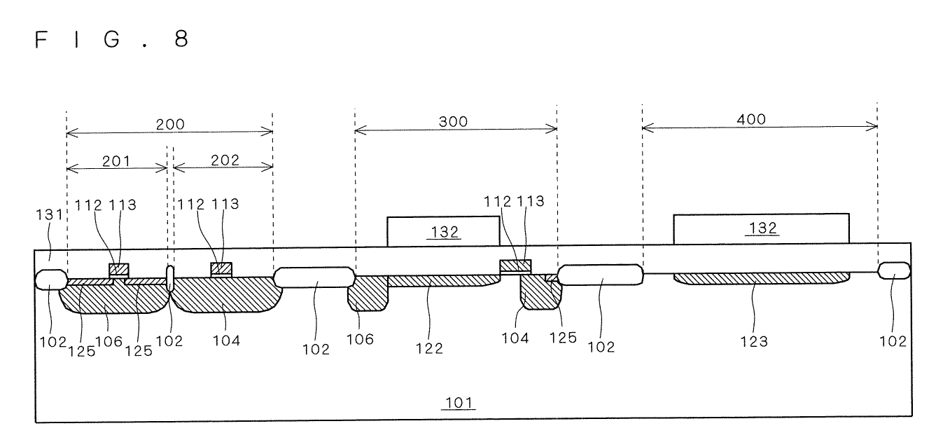

Next, as shown in FIG. 8, a photoresist 132 is formed on the TEOS film 131, and then removed by photo engraving so as to be partially left. As described above, since this photoresist 132 is of positive or negative type opposite to the type of the photoresist 121, the photoresists 121 and 132 can be formed by use of the one kind of mask. It is thereby possible to reduce kinds of masks, so as to reduce the manufacturing cost.

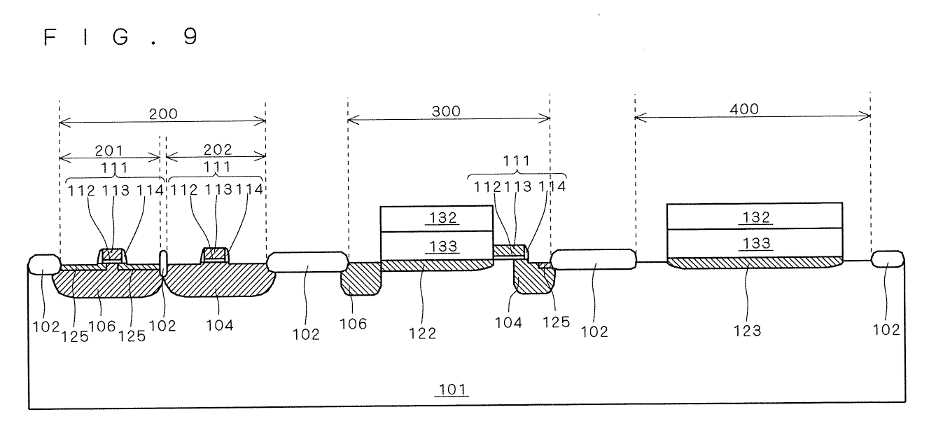

Next, as shown in FIG. 9, the TEOS film 131 is etched back except for the portion just under the photoresist 132. This leads to formation of the contamination protective film 133 just under the photoresist 132, and formation of the side wall 114 on the side face of each of the gate electrodes 113. Namely, gate structures 111, each comprised of the gate oxide film 112, the gate electrode 113 and the side wall 114, are formed. In addition, in the present embodiment, the regions where the contamination protective film 133 is formed (i.e. the p-offset region 122 and the diffusion region 123) agree with the regions not to be silicided. Therefore, the contamination protective film 133 also functions as a silicide protective film for forming a silicide region in a later process.

In addition, in FIG. 9, a level difference occurs between the silicon interface of the region just under the gate electrode 113 and the region not just under the gate electrode 113 (except for the element separation film 102), as in the conventional semiconductor device described above as the background of the invention. However, in the present embodiment, since the TEOS film 131 is etched back in a state of being covered with the photoresist 132 in the p-offset region 122 and the diffusion region 123, the silicon layer is not over-etched as in the region just under the gate electrode 113. Therefore, the silicon interfaces in the p-offset region 122 and the diffusion region 123 have the same height as that of the silicon interface just under the gate electrode 113.

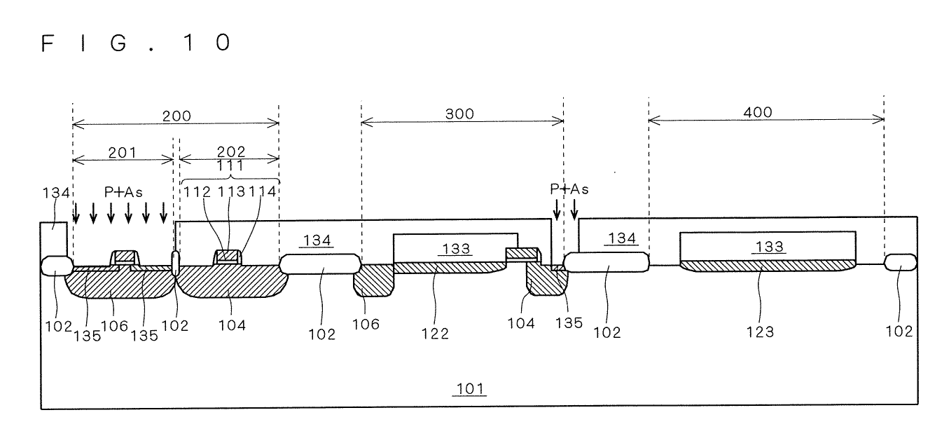

Next, as shown in FIG. 10, the photoresist 132 is removed, and a photoresist 134 is formed and partially opened by photo engraving. Subsequently, high-concentration P and As are implanted from the above to form n+ source-drain regions 135 (second region). Thereby, the n+ source-drain regions 135 are formed in the regions which are the openings of the photoresist 134 and where the gate structure 111 is not disposed (the same as the regions where the LDD regions 125 are formed in FIG. 6) among the regions on the substrate 101.

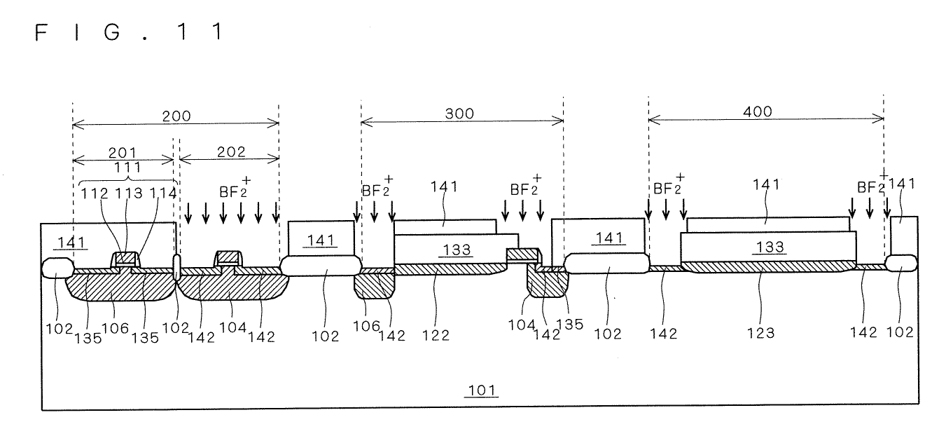

Next, as shown in FIG. 11, a photoresist 141 is formed on the substrate 101, and partially opened by photo engraving. Subsequently, BF₂+is implanted from the above to form p+ source-drain regions 142. Thereby, the p+ source-drain regions 142 are formed in the regions which are the openings of the photoresist 141 and where the gate structure 111 and the contamination protective film 133 are not disposed (the outside of the gate electrode 113 of the n-well 104 in the nMOS region 202, the whole of the p-well 106 at the left end of the HVpMOS region 300, about the center of the n-well 104 at the right end of the HVpMOS region 300, and each end of the resistor region 400) among the regions on the substrate 101.

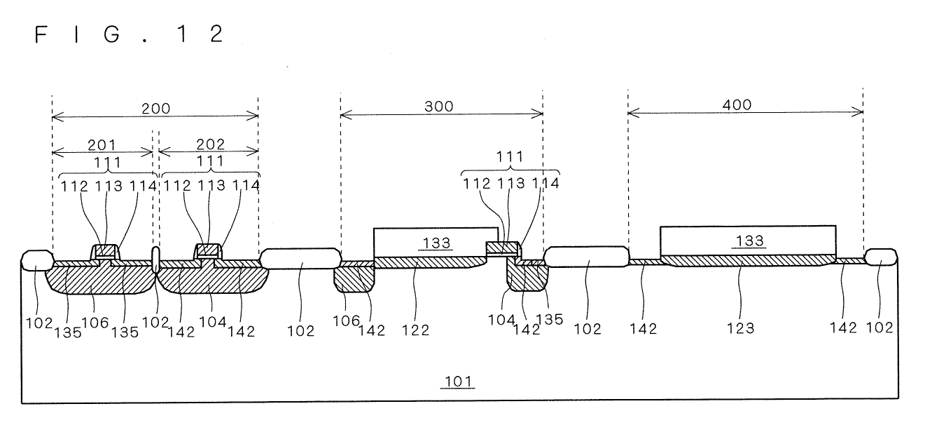

Next, as shown in FIG. 12, after removal of the photoresist 141, a silicide material such as TiN or Co is added from the above by sputtering. Thereby, a silicide region (not shown) is formed in the region where the contamination protective film 133 is not formed among the regions on the substrate 101. As described above, in the present embodiment, since the region to be protected from contamination agrees with the region not to be silicided, the contamination protective film 133 also functions as the silicide protective film. Hence protection from contamination and protection from silicide are both possible by means of the photoresist 132 formed using one kind of mask. This thus allows reduction in kinds of masks so as to reduce the manufacturing cost. In a typical manufacturing process for semiconductor devices, metal silicide is formed on a source-drain region for the purpose of lowering electrode resistance. However, when a region not to be silicided agrees with a region to be protected in active regions except for the source drain region, the effect as thus described is exerted.

As described above, in the method for manufacturing the semiconductor device according to the present embodiment, the contamination protective film 133 made of the TEOS film 131 is formed in the p-offset region 122 and the diffusion region 123 as the low-concentration implantation regions. Therefore, in a semiconductor device based on the 0.25 μm CMOS rule, it is possible to protect the p-offset region 122 and the diffusion region 123 from contamination of P or the like which was injected at a high concentration in formation of the n-well 104 and the n+ source-drain region 135. Accordingly, it is possible to reduce variations in concentration and impurity profile of the diffusion layer in the active region, so as to prevent troubles such as variations in resistance value of a diffused resistor and defect in withstand voltage.

Further, in the method for manufacturing the semiconductor device according to the present embodiment, the mask for forming the p-offset region 122 and the diffusion region 123 as the low-concentration implantation regions (i.e. mask used for opening the photoresist 121) is also used for formation of the contamination protective film 133 (i.e. opening the photoresist 132). This exerts the effect of allowing reduction in number of steps and kinds of masks so as to reduce the manufacturing cost.

Further, in the method for manufacturing the semiconductor device according to the present embodiment, when the region to be protected from contamination agrees with the region not to be silicided, the mask used for silicidation is also used for formation of the contamination protective film 133. This exerts the effect of allowing further reduction in number of steps and kinds of masks so as to reduce the manufacturing cost.

### Embodiment 2

In Embodiment 1, the p-offset region 122 and the diffusion region 123 are formed simultaneously by implanting the low concentration impurities, and the mask used for the implantation is also used for formation of the contamination protective film 133. However, the mask used for formation of the contamination protective film 133 is not limited to the mask used for formation of the p-offset region 122 and the diffusion region 123, but another mask used for formation of a typical low-concentration implantation region may also be applied. Further, a plurality of (kinds of) low-concentration implantation regions may be formed in separate steps. In a method for manufacturing a semiconductor device according to Embodiment 2, a case is described where two kinds of low-concentration implantation regions are formed on the substrate 101 in separate steps.

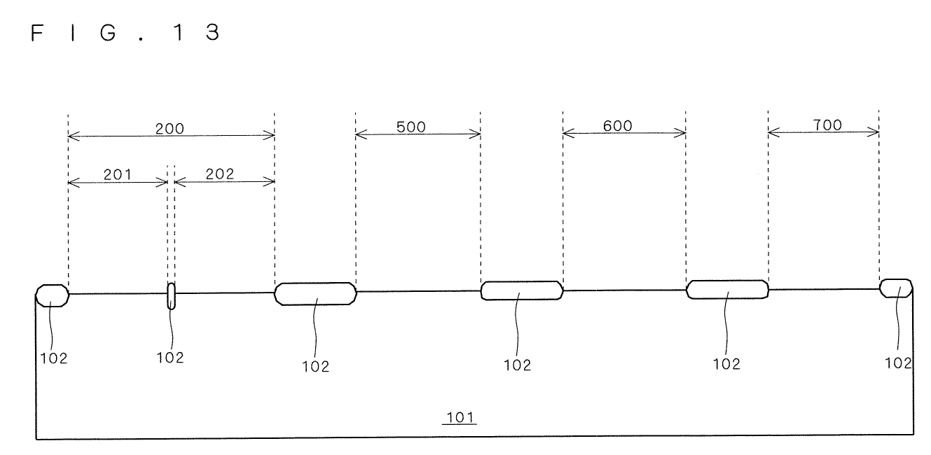

First, as shown in FIG. 13, field oxidation, photo engraving, etching, resist removal, and the like are sequentially performed on a substrate 101 made of a semiconductor to form an element separation film 102. This separates the substrate 101 into a CMOS region 200 where a CMOS element is formed, active regions 500, 600 which have low impurity concentrations and are required to be protected from contamination, and an active region 700 which has a high impurity concentration and is not required to be protected from contamination (or causes contamination). The CMOS region 200 is further separated into a PMOS region 201 and an nMOS region 202.

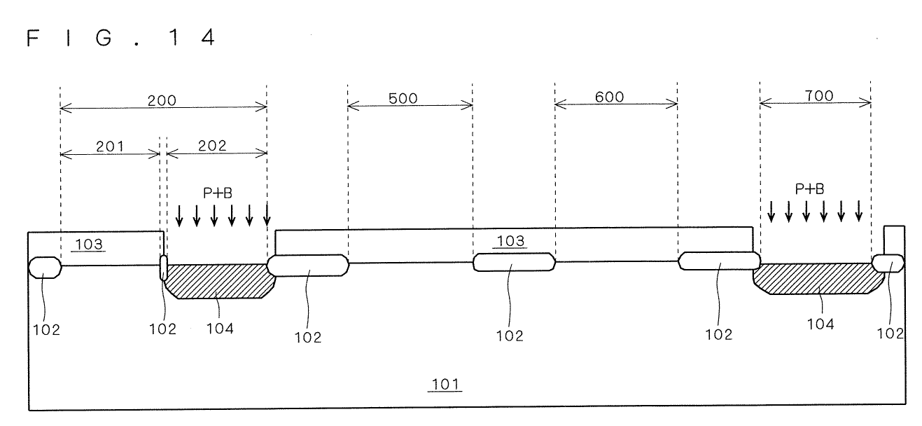

Next, as shown in FIG. 14, a photoresist 103 is formed on the substrate 101, and partially opened by photo engraving. Subsequently, B and high-concentration P are implanted from the above, to form n-wells 104. Thereby, the n-wells 104 (second region) are formed in the regions which are the openings of the photoresist 103 (the entire n-MOS region 202 and the entire active region 700) among the regions on the substrate 101.

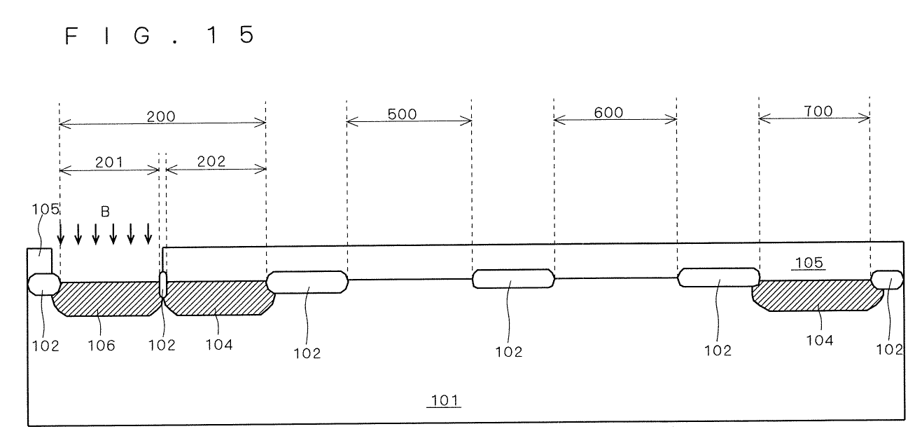

Next, as shown in FIG. 15, the photoresist 103 is removed, and a photoresist 105 is formed on the substrate 101 and partially opened by photo engraving. Subsequently, B is implanted from the above to form a p-well 106. Thereby, the p-well 106 is partially formed in the region which is the opening of the photoresist 105 (the entire PMOS region 201) among the regions on the substrate 101.

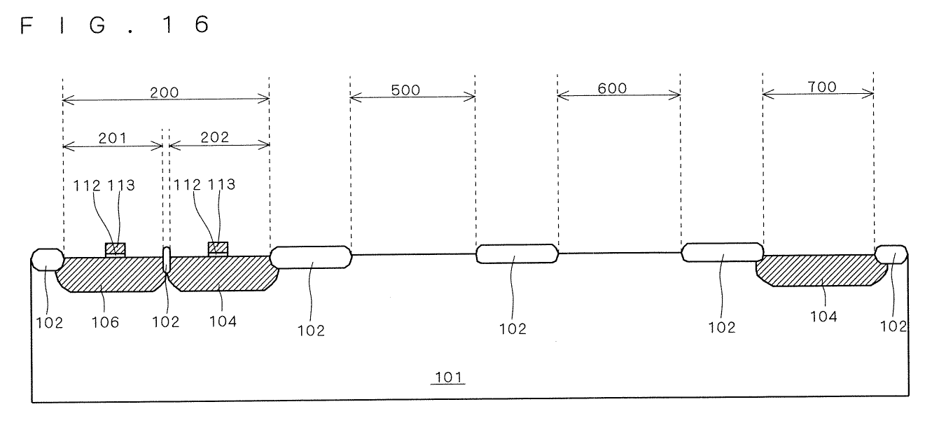

Next, as shown in FIG. 16, gate oxidation, silicon deposition, photo engraving, etching, resist removal, and the like are sequentially performed on the substrate 101, to partially form the gate oxide film 112 and the gate electrode 113 in the pMOS region 201 and the nMOS region 202. It is to be noted that the gate oxide film 112 and the gate electrode 113 are disposed in about the center of each of the pMOS region 201 and the nMOS region 202.

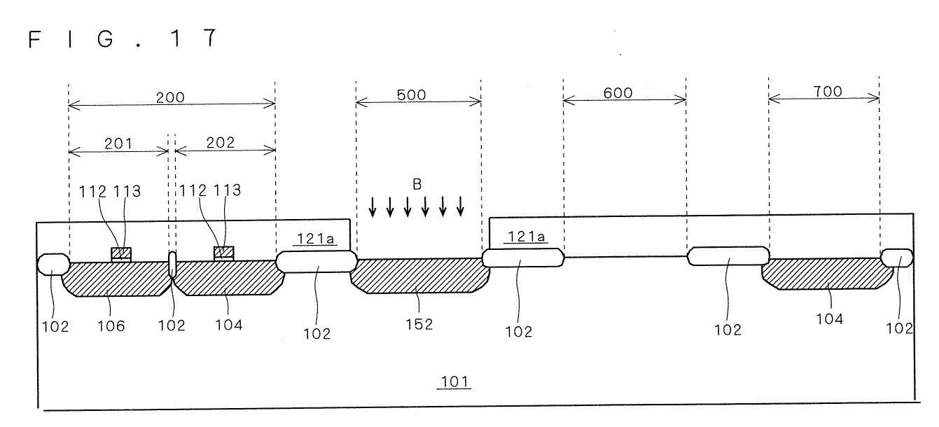

Next, as shown in FIG. 17, a photoresist 121a is formed on the substrate 101, and partially opened by photo engraving. Subsequently, low concentration-B is implanted from the above, to form a low-concentration region 152. Thereby, the low-concentration region 152 (the entire active region 500) is partially formed in the region which is the opening of the photoresist 121a among the regions on the substrate 101.

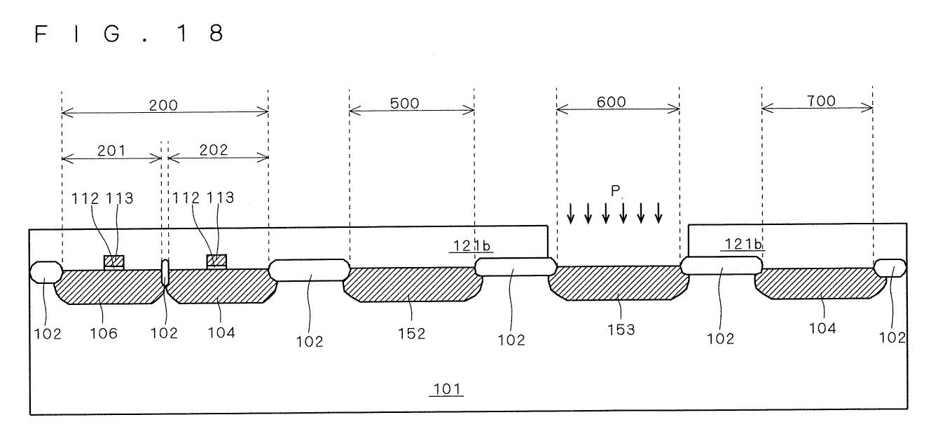

Next, as shown in FIG. 18, the photoresist 121a is removed, and a photoresist 121b is formed on the substrate 101 and partially opened by photo engraving. Subsequently, low-concentration P is implanted from the above to form a low-concentration region 153. Thereby, the low-concentration region 153 (the entire active region 600) is partially formed in the region which is the opening of the photoresist 121b among the regions on the substrate 101.

As described above, the low-concentration regions 152, 153 are required to be protected from contamination. In the present embodiment, in a later process, the contamination protective film 133 is formed on the low-concentration regions 152, 153, by use of the photoresist 132. Therefore, the respective masks used for formation of the photoresists 121a, 121b can be used for formation of the photoresist 132 (namely, it is possible to form the photoresist 132 of positive or negative type opposite to the photoresist 121 by combination of the mask used for formation of the photoresist 121a and the mask used for formation of the photoresist 121b. Namely, the low-concentration regions 152, 153 correspond to the first region according to the present invention.

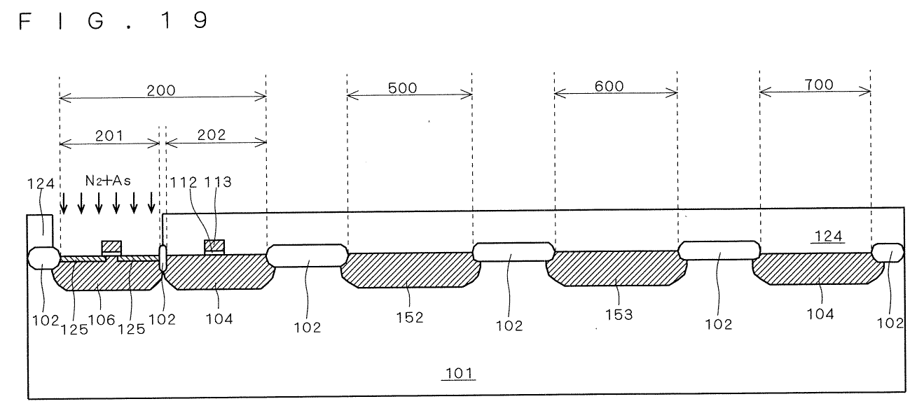

Next, as shown in FIG. 19, the photoresist 121 is removed, and a photoresist 124 is formed on the substrate 101 and partially opened by photo engraving. Subsequently, N₂ and As are implanted from the above to form an LDD region 125. Thereby, the LDD region 125 is formed in the region which is the opening of the photoresist 124 and where the gate electrode 113 is not disposed (the outside of the gate electrode 113 of the p-well 106 in the pMOS region 201) among the regions on the substrate 101.

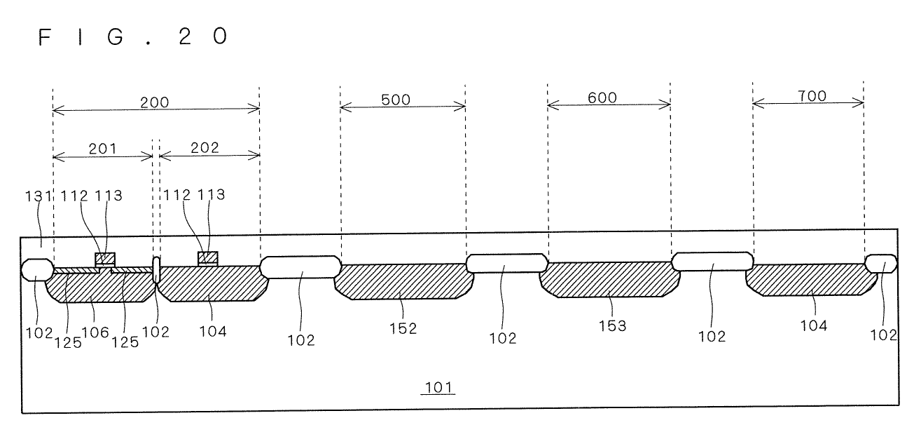

Next, as shown in FIG. 20, the photoresist 124 is removed and a TEOS film 131 with a thickness of not less than 1000 Å is formed all over the substrate 101. It is to be noted that the TEOS film 131 serves to form the side wall 114 and the contamination protective film 133 in a later process. Further, not only TEOS but also another oxide film made of NSG or the like may be used.

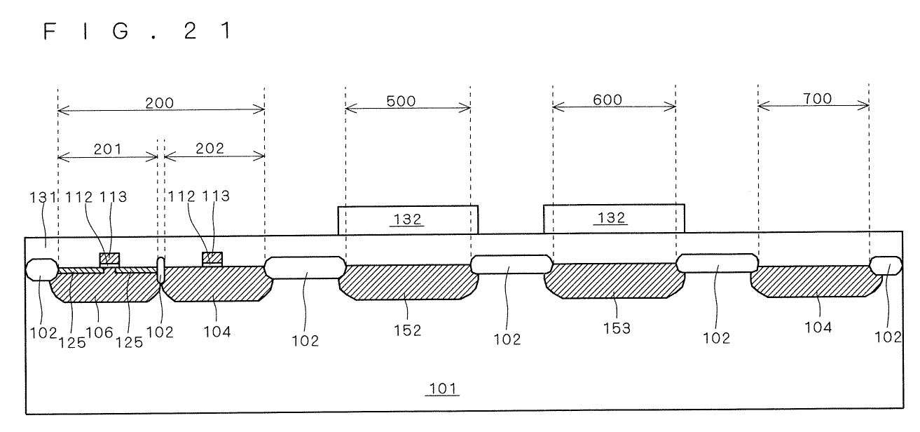

Next, as shown in FIG. 21, a photoresist 132 is formed on the TEOS film 131, and then removed by photo engraving so as to be partially left. As described above, since this photoresist 132 is formed by use of the masks for formation of the photoresists 121a, 121b, the photoresists 121a, 121b, 132 can be formed by use of two kinds of masks. It is thereby possible to reduce kinds of masks so as to reduce the manufacturing cost.

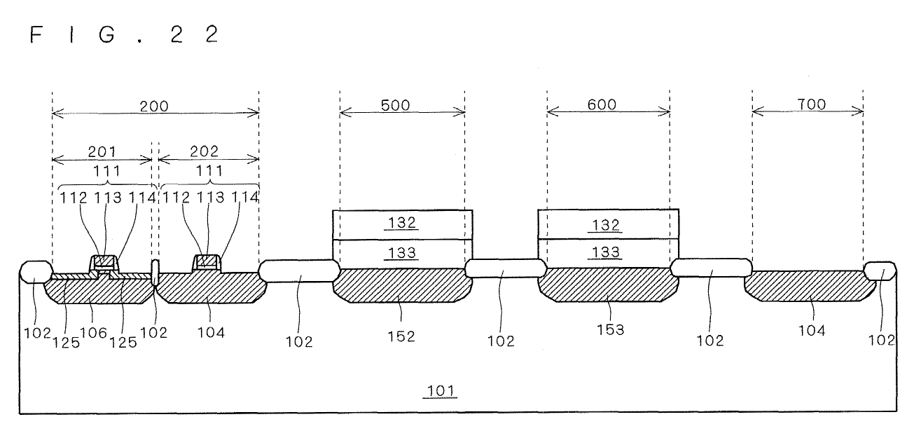

Next, as shown in FIG. 22, the TEOS film 131 is etched back except for the portion just under the photoresist 132. This leads to formation of the contamination protective film 133 just under the photoresist 132, and formation of the side wall 114 on the side face of each of the gate electrodes 113. Namely, gate structures 111, each comprised of the gate oxide film 112, the gate electrode 113 and the side wall 114, are formed. In addition, in the present embodiment, the regions where the contamination protective film 133 is formed (i.e. the low-concentration regions 152, 153) agree with the regions not to be silicided. Therefore, the contamination protective film 133 also functions as a silicide protective film for forming a silicide region in a later process.

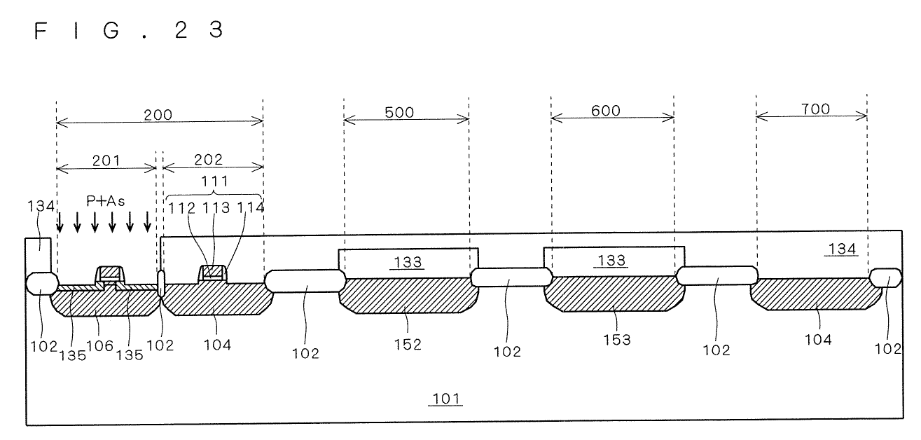

Next, as shown in FIG. 23, the photoresist 132 is removed, and a photoresist 134 is formed and partially opened by photo engraving. Subsequently, high-concentration P and As are implanted from the above to form an n+ source-drain region 135 (second region). Thereby, the n+ source-drain region 135 is partially formed in the region which is the opening of the photoresist 134 and the gate structure 111 is not disposed (the same as the region where the LDD region 125 is formed in FIG. 19) among the regions on the substrate 101.

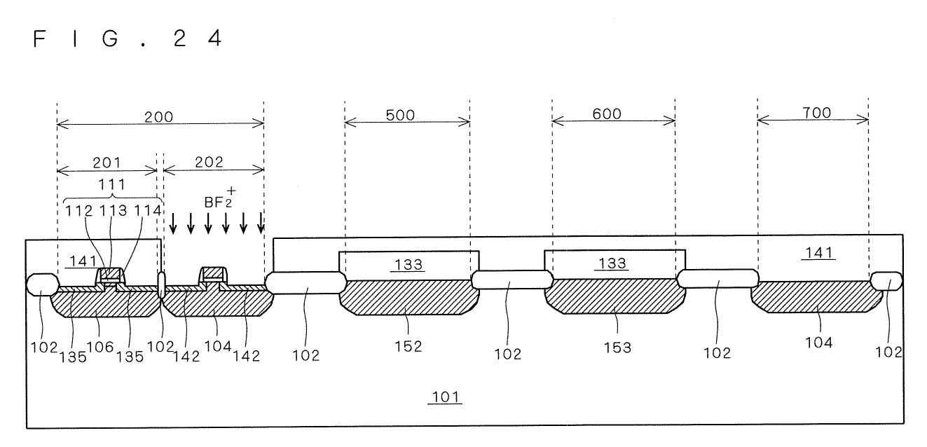

Next, as shown in FIG. 24, a photoresist 141 is formed on the substrate 101, and partially opened by photo engraving. Subsequently, BF₂+is implanted from the above to form a p+ source-drain region 142. Thereby, the p+ source-drain regions 142 is formed in the region which is the opening of the photoresist 141 and where the gate structure 111 and the contamination protective film 133 are not disposed (the outside of the gate electrode 113 of the n-well 104 in the nMOS region 202) among the regions on the substrate 101.

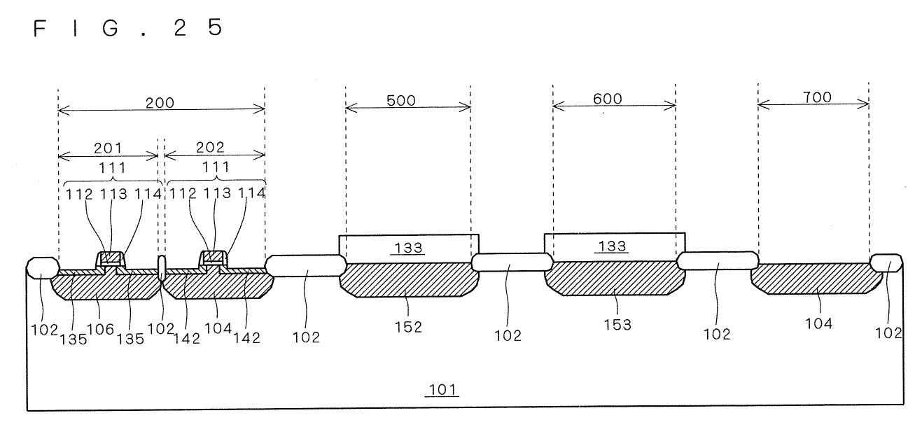

Next, as shown in FIG. 25, after removal of the photoresist 141, a silicide material such as TiN or Co is added from the above by sputtering. Thereby, a silicide region (not shown) is formed in a region where the contamination protective film 133 is not formed among the regions on the substrate 101. As described above, in the present embodiment, since the region to be protected from contamination agrees with the region not to be silicided, the contamination protective film 133 also functions as the silicide protective film. Hence protection from contamination and protection from silicide are both possible by means of the photoresist 132 formed using two kinds of masks. This thus allows reduction in kinds of masks so as to reduce the manufacturing cost.

As thus described, in the method for manufacturing the semiconductor device according to the present embodiment, in addition to the p-offset region 122 and the diffusion region 123 according to Embodiment 1, Embodiment 1 is applied to the active regions 500, 600 as other typical low-concentration implantation regions. This leads to exertion of the same effect as that of Embodiment 1.

In addition, although the case was described above where the two kinds of low-concentration regions 152, 153 are formed in separate steps, the number of kinds is not limited to two. Three or more kinds of low-concentration implantation regions may be formed in separate steps. (Naturally, one kind of low-concentration implantation region may be formed in one step.) Even in this case, it is possible for forming the contamination protective film 133 to use a mask as combination of n kinds of masks used for formation of n kinds of low-concentration implantation regions.

Further, in Embodiments 1 and 2, the case was described where the contamination protective film 133 is formed by use of the same mask as the mask used for formation of the silicide region and the low-concentration implantation region (the p-offset region 122, the diffusion region 123, and the low-concentration regions 152, 153). However, the present invention is not limited to this case. A different mask and a different step from the mask used for formation of the silicide region and the low-concentration implantation region and the step used for such formation may be applied to formation of the contamination protective film 133.

While the invention has been shown and described in detail, the foregoing description is in all aspects illustrative and not restrictive. It is therefore understood that numerous modifications and variations can be devised without departing from the scope of the invention.

What is claimed is:

1. A method for manufacturing a semiconductor device, comprising:
a first region formation step of selectively implanting impurities at a low concentration of not more than 1×10¹⁷ cm⁻³ into a semiconductor substrate to form a first region;
a contamination protective film formation step of forming a contamination protective film on said first region; and
a second region formation step of selectively implanting impurities at a high concentration of not less than 1×10¹⁸ cm⁻³ into said semiconductor substrate to form a second region at least either prior to or after said first region formation step and said contamination protective film formation step.

2. The method for manufacturing the semiconductor device according to claim 1, wherein
in said first region formation step, a first photoresist is formed by use of a prescribed mask, and
in said contamination protective film formation step, a second photoresist of a positive or negative type opposite to a type of said first photoresist is formed by use of said prescribed mask.

3. The method for manufacturing the semiconductor device according to claim 1, further comprising
a step of selectively implanting a silicide material into said substrate by use of said contamination protective film as a silicide protective film.

4. The method for manufacturing the semiconductor device according to claim 2, further comprising
a step of selectively implanting a silicide material into said substrate by use of said contamination protective film as a silicide protective film.

5. The method for manufacturing the semiconductor device according to claim 1, wherein
in said second region formation step, phosphorous is implanted as said impurities.

6. The method for manufacturing the semiconductor device according to claim 2, wherein
in said second region formation step, phosphorous is implanted as said impurities.

7. The method for manufacturing the semiconductor device according to claim 3, wherein
in said second region formation step, phosphorous is implanted as said impurities.

8. The method for manufacturing the semiconductor device according to claim 4, wherein
in said second region formation step, phosphorous is implanted as said impurities.

9. The method for manufacturing the semiconductor device according to claim 5, wherein
said first region includes at least either an offset region of a high-voltage field effect transistor or a diffused resistor region.

10. The method for manufacturing the semiconductor device according to claim 6, wherein
said first region includes at least either an offset region of a high-voltage field effect transistor or a diffused resistor region.

11. The method for manufacturing the semiconductor device according to claim 7, wherein
said first region includes at least either an offset region of a high-voltage field effect transistor or a diffused resistor region.

12. The method for manufacturing the semiconductor device according to claim 8, wherein
said first region includes at least either an offset region of a high-voltage field effect transistor or a diffused resistor region.

13. A semiconductor device comprising:
a first region selectively formed on a semiconductor substrate and containing impurities at a low concentration of not more than 1×10¹⁷ cm⁻³; and
a source-drain region selectively formed on said semiconductor substrate, containing impurities at a high concentration of not less than 1×10¹⁸ cm⁻³, and located with a surface thereof below a surface of said first region.

14. The semiconductor device according to claim 13, wherein
a surface of a region just under a gate electrode disposed in proximity to said source-drain region has the same height as the surface of said first region.

15. The semiconductor device according to claim 13, wherein
said first region includes at least either an offset region of a high-voltage field effect transistor or a diffused resistor region.

16. The semiconductor device according to claim 14, wherein
said first region includes at least either an offset region of a high-voltage field effect transistor or a diffused resistor region.
